(19) United States
(12) Patent Application Publication
(10) Pub. No.: US 2026/0303030 A1
(43) Pub. Date: Oct. 1, 2026

(54) POWER AMPLIFIER CIRCUIT AND COMMUNICATION DEVICE INCLUDING THE SAME

(71) Applicant: Murata Manufacturing Co., Ltd., Nagaokakyo-shi (JP)

(72) Inventor: Kenji TAHARA, Nagaokakyo-shi (JP)

(21) Appl. No.: 19/631,292

(22) Filed: Mar. 27, 2026

(30) Foreign Application Priority Data
Mar. 31, 2025 (JP) 2025-057805

(51) Int. Cl. H03F 1/02; H03F 3/24

(52) U.S. Cl. CPC H03F 1/0288; H03F 3/245; H03F 2200/451

(57) ABSTRACT

A power amplifier circuit includes an input terminal, a transmission terminal, and a transmission circuit. The transmission circuit amplifies a radio frequency signal supplied from an RFIC and received at the input terminal and transmits the radio frequency signal to an antenna via the transmission terminal. The transmission circuit includes power amplifiers formed on or in a substrate, and a power amplifier formed on or in a substrate. The substrates are each a semiconductor substrate including a material mainly composed of a compound of Group III and Group V elements. These power amplifiers constitute a Doherty amplifier. The substrate is a wide bandgap semiconductor substrate, and the substrate is a narrow bandgap semiconductor substrate.

### CROSS REFERENCE TO RELATED APPLICATION

This application claims priority from Japanese Patent Application No. 2025-057805, filed on Mar. 31, 2025. The content of these applications are incorporated herein by reference in its entirety.

### BACKGROUND OF THE DISCLOSURE

### Field of the Disclosure

The present disclosure relates to a power amplifier circuit and a communication device including the same, and more specifically relates to the configuration of a power amplifier circuit suitable for a low frequency band in sixth generation (6G) mobile communication systems.

### Description of the Related Art

United States Patent Application Publication No. 2022/0416725 (Patent Document 1) discloses a Doherty amplifier usable in a wireless communication system. In Patent Document 1, a final stage power amplifier in each of amplification paths constituting a carrier amplifier and a peak amplifier of a Doherty amplifier is implemented using an integrated circuit (IC) die using a III-V material such as gallium nitride (GaN). On the other hand, a driver stage amplifier for driving the final stage power amplifier is implemented using an IC die using a Si-based material such as silicon germanium (SiGe) or an IC die using a III-V material.

### BRIEF SUMMARY OF THE DISCLOSURE

In recent years, 6G communication systems have been developed to implement higher-speed and larger-capacity communications in wireless communication devices. In 6G communication systems, communication capability exceeding 100 Gbps is enabled by using so-called sub-terahertz waves exceeding 100 GHz, in which a frequency band wider than in 5G communication systems that use an existing millimeter wave frequency band (20 GHz to 70 GHz) can be utilized.

Sub-terahertz waves as described above have characteristics of high directivity and short communication ranges. Accordingly, sub-terahertz waves can be used in an environment where many antennas for base stations are installed, such as in urban areas, but are unsuitable for wireless communication access in an environment where many base stations cannot be installed, such as in the sky, over the sea, or in outer space. Thus, to construct a 6G communication system network in a wide range of area, sub-terahertz wave communication alone is insufficient, and it is necessary to additionally use communication using millimeter waves or radio waves of a lower frequency band, although the communication capacity thereof is lower.

As a low frequency band used in 6G communication systems, centimeter waves such as a frequency band called "Frequency Range 3 (FR3)" around 7 GHz to 10 GHz has been studied for use.

In the frequency band of FR3 and a frequency band called "Ultra High Band (UHB)" around 3.3 GHz to 5.0 GHz, the wavelength of a radio frequency (RF) signal is longer than the millimeter wavelength. Thus, it may be difficult to use a flat-shaped patch antenna particularly in a compact mobile terminal such as a smartphone, from the viewpoint of implementation. This makes it impossible to extend the coverage by beamforming. Thus, use of centimeter waves, such as FR3or UHB, requires high power radiation of radio waves to extend the coverage.

In an existing technique for implementing high output of a power amplifier circuit, a semiconductor is formed by employing an IC die using a material mainly composed of a III-V base material as a power amplifier, as in the aforementioned Patent Document 1. Among such materials, GaN is capable of maintaining high output up to a relatively high frequency band, as compared with other III-V materials such as GaAs. However, GaN is a wide bandgap semiconductor and is incapable of operating at a low voltage such as 1.0 V, and thus the operating current in a low voltage region is higher than that of other materials. That is, GaN has a property of being incapable of performing power saving operation and thus incapable of reducing power consumption. This can be a non-negligible problem in devices that use batteries as power sources, such as mobile terminals.

The present disclosure has been made to solve the above-described issues, and the possible benefit thereof is to reduce power consumption at low voltages and implement high output in a power amplifier circuit used in 6G communication systems.

A power amplifier circuit according to the present disclosure is used to amplify a radio frequency signal supplied from a signal processing circuit and transmit the radio frequency signal to an antenna. The power amplifier circuit includes an input terminal, a transmission terminal, and a transmission circuit. At the input terminal, a radio frequency signal to be transmitted is received from the signal processing circuit. Via the transmission terminal, the radio frequency signal is transmitted to the antenna. The transmission circuit amplifies the radio frequency signal received at the input terminal and transmits the radio frequency signal to the antenna via the transmission terminal. The transmission circuit includes a first substrate and a second substrate, and a first amplification circuit and a second amplification circuit formed on or in the first substrate and the second substrate, respectively. The first substrate and the second substrate are each constituted by a semiconductor substrate including a material mainly composed of a compound of Group III and Group V elements. The first amplification circuit and the second amplification circuit constitute a Doherty amplifier. The first substrate is a wide bandgap semiconductor substrate, and the second substrate is a narrow bandgap semiconductor substrate.

The power amplifier circuit according to the present disclosure includes the first amplification circuit formed on or in the wide bandgap semiconductor substrate (first substrate) and the second amplification circuit formed on or in the narrow bandgap semiconductor substrate (second substrate). Accordingly, the use of the first amplification circuit of a wide bandgap semiconductor having a high withstand voltage and capable of high-temperature operation makes it possible to achieve high output, and the use of the second amplification circuit of a narrow bandgap semiconductor during low voltage operation makes it possible to implement low power consumption.

### BRIEF DESCRIPTION OF THE SEVERAL VIEWS OF THE DRAWINGS

FIG. 1 is a schematic configuration diagram of a transmission device including a power amplifier circuit according to a first embodiment;

FIG. 2 is a diagram illustrating a detailed configuration of the power amplifier circuit illustrated in FIG. 1;

FIG. 3 is a diagram for describing output states of individual amplifiers in a first mode in the case of transmitting a radio frequency (RF) signal of Frequency Range 3 (FR3);

FIG. 4 is a diagram for describing output states of individual amplifiers in a second mode in the case of transmitting an RF signal of FR3;

FIG. 5 is a diagram for describing output states of individual amplifiers in a third mode in the case of transmitting an RF signal of FR3;

FIG. 6 is a graph for describing the relationship between output power and efficiency in the case of transmitting an RF signal of FR3;

FIG. 7 is a diagram for describing output states of individual amplifiers in a first mode in the case of transmitting an RF signal of Ultra High Band (UHB);

FIG. 8 is a diagram for describing output states of individual amplifiers in a second mode in the case of transmitting an RF signal of UHB;

FIG. 9 is a diagram for describing output states of individual amplifiers in a third mode in the case of transmitting an RF signal of UHB;

FIG. 10 is a diagram illustrating a detailed configuration of a power amplifier circuit according to a second embodiment;

FIG. 11 is a diagram for describing output states of individual amplifiers in a first mode in the case of transmitting an RF signal of FR3;

FIG. 12 is a diagram for describing output states of individual amplifiers in a second mode in the case of transmitting an RF signal of FR3;

FIG. 13 is a diagram for describing output states of individual amplifiers in a third mode in the case of transmitting an RF signal of FR3;

FIG. 14 is a graph for describing the relationship between output power and efficiency in the case of transmitting an RF signal of FR3;

FIG. 15 is a diagram for describing output states of individual amplifiers in a first mode in the case of transmitting an RF signal of UHB;

FIG. 16 is a diagram for describing output states of individual amplifiers in a second mode in the case of transmitting an RF signal of UHB;

FIG. 17 is a diagram for describing output states of individual amplifiers in a third mode in the case of transmitting an RF signal of UHB; and

FIG. 18 is a diagram illustrating a detailed configuration of a power amplifier circuit according to a third embodiment.

### DETAILED DESCRIPTION OF THE DISCLOSURE

Hereinafter, embodiments of the present disclosure will be described in detail with reference to the accompanying drawings. The same or equivalent parts in the drawings are denoted by the same reference numerals, and the description thereof will not be repeated.

### First Embodiment

### Overall Configuration of Communication Device

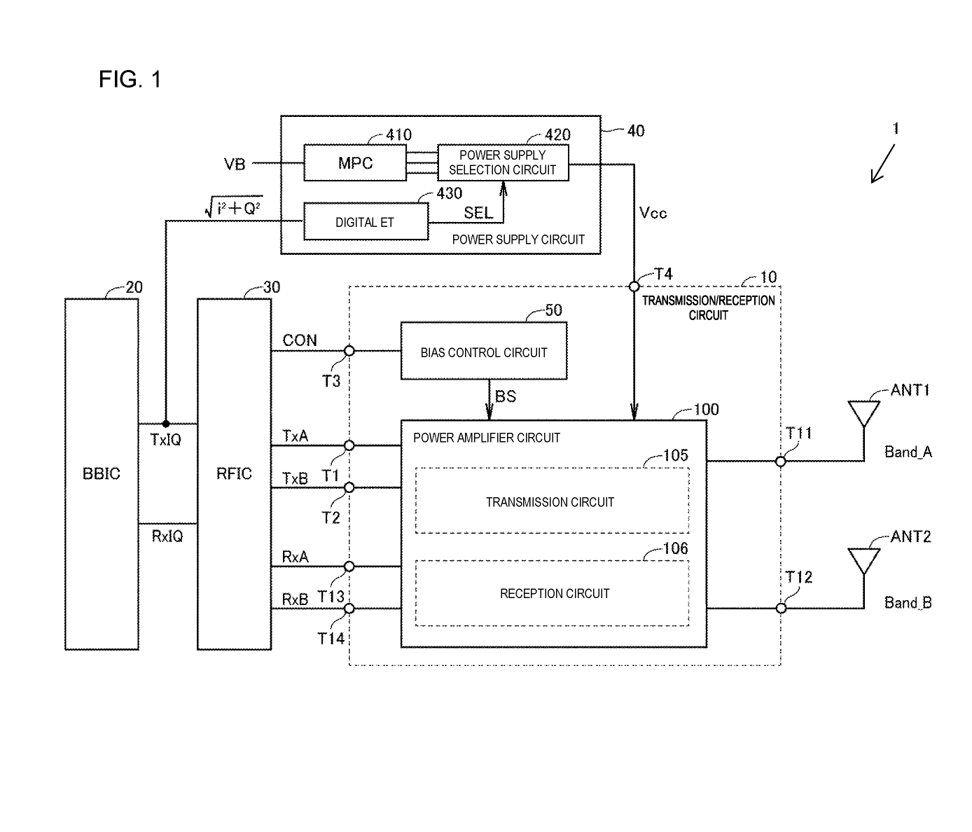

FIG. 1 is a schematic configuration diagram of a communication device 1 including a transmission/reception circuit 10 according to an embodiment. The communication device 1 is, for example, a mobile terminal such as a mobile phone, a smartphone, or a tablet, or a personal computer having a communication function.

Referring to FIG. 1, the communication device 1 includes antennas ANT1 and ANT2, the transmission/reception circuit 10, a baseband integrated circuit (BBIC) 20 constituting a baseband signal processing circuit, a radio frequency integrated circuit (RFIC) 30 that functions as an RF signal processing circuit, and a power supply circuit 40. The transmission/reception circuit 10 includes input terminals T1 to T4, antenna terminals T11 and T12, output terminals T13 and T14, a bias control circuit 50, and a power amplifier circuit 100. The power amplifier circuit 100 includes a transmission circuit 105 and a reception circuit 106.

In the communication device 1, schematically, the RFIC 30 upconverts an intermediate frequency (IF) signal received from the BBIC 20 into a radio frequency (RF) signal, the transmission circuit 105 of the power amplifier circuit 100 amplifies the RF signal, and the amplified RF signal is radiated from the antenna ANT1 or ANT2. In addition, in the communication device 1, the reception circuit 106 amplifies an RF signal received by the antenna ANT1 or ANT2 at low noise, and outputs the amplified RF signal to the RFIC 30.

The RFIC 30 is an example of a signal processing circuit that processes an RF signal. The RFIC 30 upconverts an IF signal received from the BBIC 20 into an RF signal. The RFIC 30 outputs the RF signal, which serves as a transmission signal TxIQ, to the transmission/reception circuit 10 via the input terminal T1 or T2. In addition, the RFIC 30 acquires, from the reception circuit 106 via the output terminal T13 or T14, an RF signal received by the antenna ANT1 or ANT2, downconverts the RF signal into an IF signal, and outputs the IF signal, which serves as a reception signal RxIQ, to the BBIC 20.

The power supply circuit 40 is an example of a so-called digital tracker and is capable of supplying power supply voltages Vcc of a plurality of different voltage levels to the power amplifier circuit 100. The power supply circuit 40 includes a multilevel power converter (MPC) 410, a power supply selection circuit 420, and a digital envelope tracker (digital ET) 430.

The MPC 410 includes a plurality of DC/DC converters, although not illustrated in FIG. 1. The MPC 410 converts a battery voltage VB supplied from an external battery to a plurality of different voltage levels and supplies the voltage levels to the power supply selection circuit 420.

The digital ET 430 receives an I/Q waveform signal of a transmission signal TxIQ from the BBIC 20 and tracks the envelope of the transmission signal by a digital ET mode. The digital ET 430 generates a selection signal SEL corresponding to the voltage level of the envelope of the transmission signal and outputs the selection signal SEL to the power supply selection circuit 420.

The power supply selection circuit 420 selects, from among the plurality of voltage levels supplied from the MPC 410, a voltage corresponding to the selection signal SEL, and supplies the selected voltage, which serves as a power supply voltage Vcc, to the power amplifier circuit 100 via the input terminal T4.

The bias control circuit 50 receives a control signal CON from the RFIC 30 via the input terminal T3. The bias control circuit 50 generates, based on the control signal CON, a bias signal BS for controlling the magnitude and supply timing of a bias current of an amplification circuit included in the power amplifier circuit 100, and outputs the bias signal BS to the power amplifier circuit 100.

The power amplifier circuit 100 amplifies input signals TxA and TxB received from the RFIC 30 via the input terminals T1 and T2, respectively, and generates output signals. The generated output signals are transferred to the respective antennas ANT1 and ANT2 via the antenna terminals T11 and T12, respectively, and radiated as radio waves from the antennas ANT1 and ANT2. The antennas ANT1 and ANT2 are typically linear antennas such as monopole antennas, dipole antennas, or inverted-F antennas.

The input signal TxA is an input signal for a first frequency band (Band_A). The input signal TxB is an input signal for a second frequency band (Band_B).

The antennas ANT1 and ANT2 have configurations adapted to radio waves of frequency bands different from each other. For example, the antenna ANT1 has a size capable of radiating radio waves corresponding to the input signal TxA, and the antenna ANT2 has a size capable of radiating radio waves corresponding to the input signal TxB.

The transmission/reception circuit 10 according to the first embodiment is applicable to a circuit for transmitting and receiving a signal of a frequency band lower than that of sub-terahertz waves. In an example of the first embodiment, the first frequency band (Band_A) is the frequency band of Frequency Range 3 (FR3) around 7 GHz to 10 GHz, and the second frequency band (Band_B) is the frequency band of Ultra High Band (UHB) around 3.3 GHz to 5.0 GHz.

### Detailed Configuration of Power Amplifier Circuit

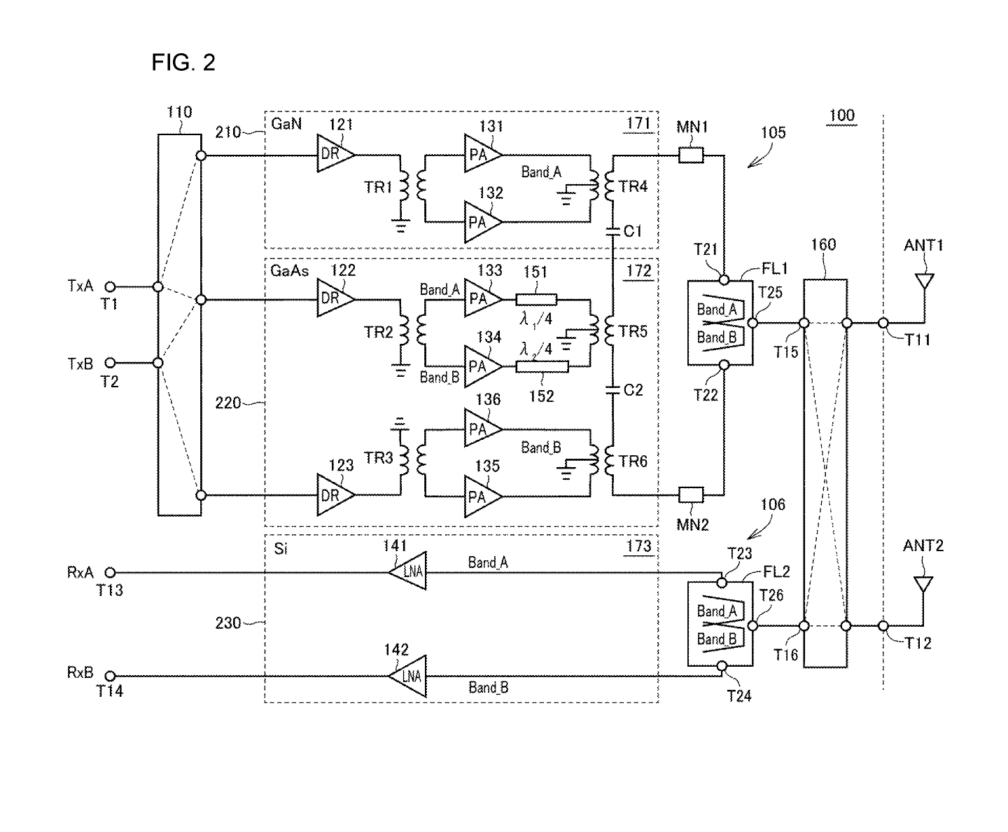

Next, a detailed configuration of the power amplifier circuit 100 will be described with reference to FIG. 2. The power amplifier circuit 100 includes, as described above, the transmission circuit 105 for amplifying a signal from the RFIC 30, and the reception circuit 106 for amplifying a reception signal from the antenna ANT1 or ANT2. The power amplifier circuit 100 further includes a switch circuit 160 for distributing an RF signal from the transmission circuit 105 to the antenna ANT1 or ANT2 and transferring a signal received by the antenna ANT1 or ANT2 to the reception circuit 106.

First, the details of the transmission circuit 105 will be described. The transmission circuit 105 includes a switch circuit 110, drive amplifiers 121 to 123, power amplifiers 131 to 136, phase shift lines 151 and 152, transformers TR1 to TR6, matching circuits MN1 and MN2, a filter circuit FL1, and capacitors C1 and C2.

The drive amplifier 121, the power amplifiers 131 and 132, the transformers TR1 and TR4, and the capacitor C1 constitute an amplification circuit 171. The drive amplifiers 122 and 123, the power amplifiers 133 to 136, the phase shift lines 151 and 152, the transformers TR2, TR3, TR5, and TR6, and the capacitor C2 constitute an amplification circuit 172.

The amplification circuit 171 is formed on or in a substrate 210, and the amplification circuit 172 is formed on or in a substrate 220. The substrates 210 and 220 are each constituted by a semiconductor substrate including a material mainly composed of a compound of group III and group V elements. More specifically, the substrate 210 is formed of a wide bandgap semiconductor substrate, for example, a semiconductor substrate including GaN having a bandgap of 3.4 eV. The substrate 220 is formed of a narrow bandgap semiconductor substrate, for example, a semiconductor substrate including GaAs having a bandgap of 1.4 eV.

The switch circuit 110 branches each of the input signals TxA and TxB received at the input terminals T1 and T2 into two paths, adjusts the phases of the branched signals, and transfers the signals to the drive amplifiers 121 to 123. The input signal TxA is transferred to the drive amplifiers 121 and 122. The input signal TxB is transferred to the drive amplifiers 122 and 123. The drive amplifier 122 receives a signal whose phase is advanced by 90 degrees compared with the RF signals transferred to the drive amplifiers 121 and 123.

The drive amplifier 121 is an amplifier for driving the power amplifiers 131 and 132. The drive amplifier 121 is connected to one end of a primary winding of the transformer TR1 that functions as a balun. The other end of the transformer TR1 is grounded. The input end of the power amplifier 131 is connected to one end of a secondary winding of the transformer TR1, and the input end of the power amplifier 132 is connected to the other end. The transformer TR1 supplies a differential signal having a phase difference of 180 degrees to the power amplifiers 131 and 132.

The output end of the power amplifier 131 is connected to one end of a primary winding of the transformer TR4. The output end of the power amplifier 132 is connected to the other end of the primary winding of the transformer TR4. The midpoint of the primary winding of the transformer TR4 is grounded.

One end of a secondary winding of the transformer TR4 is connected to a terminal T21 of the filter circuit FL1 via the matching circuit MN1. The other end of the secondary winding of the transformer TR4 is connected to one end of a secondary winding of the transformer TR5 via the capacitor C1. The matching circuit MN1 achieves impedance matching between the transformer TR4 and the filter circuit FL1.

The drive amplifier 122 is an amplifier for driving the power amplifiers 133 and 134. The drive amplifier 122 is connected to one end of a primary winding of the transformer TR2 that functions as a balun. The other end of the transformer TR2 is grounded. The input end of the power amplifier 133 is connected to one end of a secondary winding of the transformer TR2, and the input end of the power amplifier 134 is connected to the other end. The transformer TR2 supplies a differential signal having a phase difference of 180 degrees to the power amplifiers 133 and 134.

The output end of the power amplifier 133 is connected to one end of a primary winding of the transformer TR5 via the phase shift line 151. The output end of the power amplifier 134 is connected to the other end of the primary winding of the transformer TR5 via the phase shift line 152. The midpoint of the primary winding of the transformer TR5 is grounded.

The phase shift line 151 has an electrical length of one-quarter of wavelength λ₁ at the center frequency of the frequency band of FR3. The phase shift line 152 has an electrical length of one-quarter of wavelength λ₂ at the center frequency of the frequency band of UHB.

The one end of the secondary winding of the transformer TR5 is connected to the other end of the secondary winding of the transformer TR4 via the capacitor C1, as described above. The other end of the secondary winding of the transformer TR5 is connected to one end of a secondary winding of the transformer TR6 via the capacitor C2.

The drive amplifier 123 is an amplifier for driving the power amplifiers 135 and 136. The drive amplifier 123 is connected to one end of a primary winding of the transformer TR3 that functions as a balun. The other end of the transformer TR3 is grounded. The input end of the power amplifier 135 is connected to one end of a secondary winding of the transformer TR3, and the input end of the power amplifier 136 is connected to the other end. The transformer TR3 supplies a differential signal having a phase difference of 180 degrees to the power amplifiers 135 and 136.

The output end of the power amplifier 136 is connected to one end of a primary winding of the transformer TR6. The output end of the power amplifier 135 is connected to the other end of the primary winding of the transformer TR6. The midpoint of the primary winding of the transformer TR6 is grounded.

The one end of the secondary winding of the transformer TR6 is connected to the other end of the secondary winding of the transformer TR5 via the capacitor C2, as described above. The other end of the secondary winding of the transformer TR6 is connected to a terminal T22 of the filter circuit FL1 via the matching circuit MN2. The matching circuit MN2 achieves impedance matching between the transformer TR6 and the filter circuit FL1.

The power amplifiers 131, 132, and 133 are amplifiers for an RF signal of FR3. The power amplifiers 134, 135, and 136 are amplifiers for an RF signal of UHB.

As described below, in the case of transmitting an RF signal of FR3, the power amplifiers 134, 135, and 136 are set to a non-driven state. In this case, the power amplifiers 131, 132, and 133 and the phase shift line 151 constitute a Doherty amplifier in which the power amplifiers 131 and 132 serve as a carrier amplifier and the power amplifier 133 serves as a peak amplifier.

On the other hand, in the case of transmitting an RF signal of UHB, the power amplifiers 131, 132, and 133 are set to a non-driven state. In this case, the power amplifiers 134, 135, and 136 and the phase shift line 152 constitute a Doherty amplifier in which the power amplifiers 135 and 136 serve as a carrier amplifier and the power amplifier 134 serves as a peak amplifier.

The filter circuit FL1 is a diplexer including a band pass filter that allows a signal of the frequency band of FR3 to pass therethrough, and a band pass filter that allows a signal of the frequency band of UHB to pass therethrough.

The filter circuit FL1 includes the terminal T21 connected to the band pass filter for FR3, the terminal T22 connected to the band pass filter for UHB, and a common terminal T25. The filter circuit FL1 combines an RF signal for FR3 received at the terminal T21 and an RF signal for UHB received at the terminal T22, and outputs a resulting signal from the common terminal T25 to the switch circuit 160.

The capacitor C1 connected between the transformer TR4 and the transformer TR5 and the capacitor C2 connected between the transformer TR5 and the transformer TR6 are provided for adjusting a phase and harmonic waves. The capacitors C1 and C2 are not essential components and are not necessarily provided when the adjustment of a phase and harmonic waves is not necessary.

Next, the details of the reception circuit 106 will be described. The reception circuit 106 includes low-noise amplifiers 141 and 142 and a filter circuit FL2. The low-noise amplifiers 141 and 142 constitute an amplification circuit 173. The amplification circuit 173 is formed on or in a semiconductor substrate 230 including a material mainly composed of a Si-based material.

Like the filter circuit FL1, the filter circuit FL2 is a diplexer including a band pass filter that allows a signal of the frequency band of FR3 to pass therethrough, and a band pass filter that allows a signal of the frequency band of UHB to pass therethrough. The filter circuit FL2 includes terminals T23 and T24 and a common terminal T26. The filter circuit FL2 receives, at the common terminal T26, reception signals transferred from the antennas ANT1 and ANT2 via the switch circuit 160, separates the reception signals into respective frequency bands, and outputs the resulting signals from the terminals T23 and T24 to the low-noise amplifiers 141 and 142, respectively.

The low-noise amplifier 141 is an amplifier for the frequency band of FR3, amplifies an RF signal transferred from the filter circuit FL2 at low noise, and outputs the RF signal to the RFIC 30 via the output terminal T13. The low-noise amplifier 142 is an amplifier for the frequency band of UHB, amplifies an RF signal transferred from the filter circuit FL2 at low noise, and outputs the RF signal to the RFIC 30 via the output terminal T14.

The switch circuit 160 is constituted by a plurality of switching elements, for example, metal-oxide-semiconductor field-effect transistors (MOSFETs). The switch circuit 160 switches the connection of the antennas ANT1 and ANT2 with respect to the transmission circuit 105 and the reception circuit 106.

In the case of transmitting an RF signal of FR3, a transmission terminal T15, which is connected to the common terminal T25 of the filter circuit FL1, is connected to the antenna ANT1. In the case of transmitting an RF signal of UHB, the transmission terminal T15 is connected to the antenna ANT2.

In the case of receiving radio waves at the antennas ANT1 and ANT2, a reception terminal T16, which is connected to the common terminal T26 of the filter circuit FL2, is connected to the antennas ANT1 and ANT2.

As described above, the transmission/reception circuit 10 according to the first embodiment is intended to be used for communication of an RF signal of FR3 on the low frequency side relative to sub-terahertz waves. In this frequency band, restriction of the size of an antenna that can be mounted in a mobile terminal makes it impossible to use a patch antenna for millimeter waves or the like. Thus, to extend the antenna coverage, it is necessary to radiate radio waves at high power, instead of extending the coverage by beamforming using a patch antenna.

As a method of implementing high output of a power amplifier circuit, it is known to form a semiconductor substrate forming a power amplifier by using a material mainly composed of a III-V base material. In particular, among such materials, a wide bandgap semiconductor such as GaN is capable of maintaining high output even for a signal of a relatively high frequency band such as FR3. However, GaN is a wide bandgap semiconductor and is incapable of operating at a low voltage such as 1.0 V, and thus the operating current in a low voltage region is larger than that of other materials. That is, GaN has a property of being incapable of performing power saving operation and thus incapable of reducing power consumption.

On the other hand, when a substrate made of a narrow bandgap semiconductor, such as GaAs, among materials mainly composed of a III-V base material is used, the operating current in a low voltage region is very small compared to that of GaN, although the output in a high frequency region is lower than that of GaN.

Thus, in the power amplifier circuit 100 used in the transmission/reception circuit 10 according to the first embodiment, a power amplifier formed on or in a semiconductor substrate using a material mainly composed of GaN and a power amplifier formed on or in a semiconductor substrate using a material mainly composed of GaAs are used in combination, and the power amplifier to be used for amplification is switched in accordance with required output power and voltage to be used. More specifically, when high output power is necessary, the power amplifier using GaN having a high output capacity is used. On the other hand, in a region where the required output power is low (i.e., a low voltage region), the power amplifier using GaAs capable of low voltage operation is used. As a result of switching the power amplifier to be used in accordance with the condition of required power, it is possible to implement high output while reducing power consumption at low voltages.

### Description of Operation Modes

Hereinafter, operation modes in the case of transmitting RF signals of individual frequency bands of FR3 and UHB will be described. The operation modes in the individual frequency bands include a "first mode" that is used when relatively large power is required, a "second mode" that is used when medium power is required, and a "third mode" that is used during low power operation.

### (1) FR3

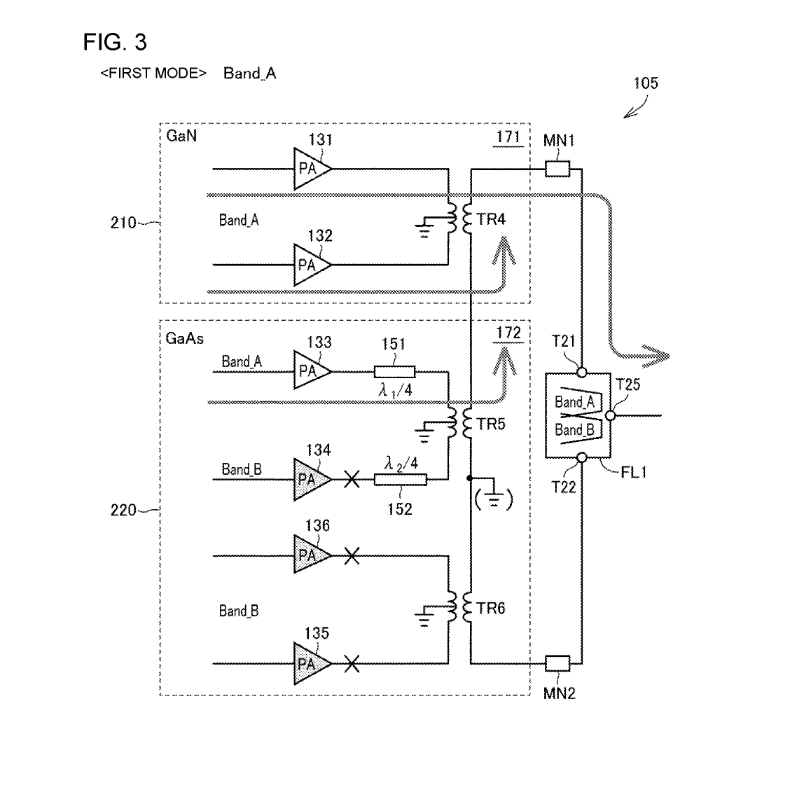

First, the operations of individual amplifiers in the case of transmitting an RF signal of the FR3 frequency band (Band_A) will be described with reference to FIGS. 3 to 6. In FIGS. 3, and in 4, 5, 7 to 9, 11 to 13, and 15 to 17 described below, the power amplifiers and their downstream configuration in the transmission circuit 105 are illustrated for simplifying the description. In these figures, the capacitor C1 between the transformer TR4 and the transformer TR5 and the capacitor C2 between the transformer TR5 and the transformer TR6 are not illustrated to describe the circuit in a simplified manner.

### 1-1 First Mode

FIG. 3 is a diagram for describing output states of individual amplifiers in a first mode in the case of transmitting an RF signal of FR3. In this operation mode, the power amplifiers 131 to 133 are set to a driven state, and the power amplifiers 134 to 136 are set to a non-driven state.

As a result of the power amplifier 134 being set to a non-driven state, the power amplifier 134 has an open-circuit impedance at the output end thereof. Thus, because of the phase shift line 152, a connection node between the phase shift line 152 and the transformer TR5 and a connection node of the secondary winding of the transformer TR5 with respect to the transformer TR6 have a short-circuit impedance. Accordingly, the signal amplified by the power amplifier 133 is transferred toward the transformer TR4. At this time, the phase of the signal is delayed by 90 degrees by the phase shift line 151.

In the power amplifiers 131 and 132 on the substrate 210 side, differential signals transferred from the transformer TR1 are respectively amplified, and the two amplified signals are combined at the transformer TR4.

The phase of an RF signal transferred from the switch circuit 110 to the drive amplifier 122 for the power amplifier 133 is advanced by 90 degrees relative to the phase of an RF signal transferred to the drive amplifier 121 for the power amplifiers 131 and 132. Thus, the phase delay produced by the phase shift line 151 causes a signal generated at the secondary winding of the transformer TR5 to have the same phase as that of a signal generated at the secondary winding of the transformer TR4. Accordingly, the signals amplified by the power amplifiers 131 and 132 and the signal amplified by the power amplifier 133 are combined in the same phase, and the resulting signal is outputted to the filter circuit FL1.

In the first mode, the power amplifiers 131 to 133 and the phase shift line 151 constitute a Doherty amplifier in which the power amplifiers 131 and 132 serve as a carrier amplifier and the power amplifier 133 serves as a peak amplifier. At the maximum power, all the power amplifiers 131 to 133 operate at the maximum output.

As the output power decreases from the maximum power, the power amplifier 133 functioning as a peak amplifier gradually turns off, and accordingly the load impedance of the power amplifiers 131 and 132 functioning as a carrier amplifier gradually increases. The increase in the load impedance improves the efficiency of the power amplifiers 131 and 132.

When the power amplifier 133 is completely brought into a non-driven state, the load impedance seen from the output ends of the power amplifiers 131 and 132 becomes 1.5 times higher, and the number of power amplifiers in use is reduced to two-thirds. This makes it possible to obtain a back-off amount of about 3.5 dB (1.76 dB × 2) as a whole.

### (1-2) Second Mode

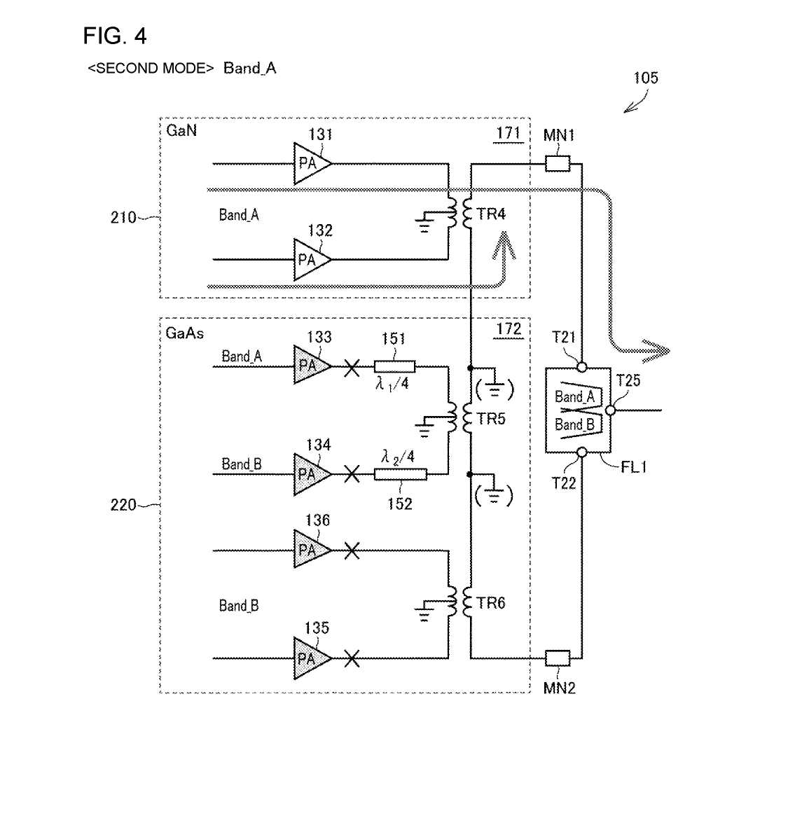

FIG. 4 is a diagram for describing output states of individual amplifiers in a second mode in the case of transmitting an RF signal of FR3.

The second mode is an operation mode that is used when the power level is lower (second power value) than the power level in the first mode (first power value). In the second mode, the power amplifier 133 is set to a non-driven state, and only the power amplifiers 131 and 132 formed on or in the substrate 210 are set to a driven state.

At this time, as a result of the power amplifier 133 being set to a non-driven state, a connection node in the secondary winding of the transformer TR5 with respect to the transformer TR4 has a short-circuit impedance. Thus, the signals amplified by the power amplifiers 131 and 132 are combined at the transformer TR4, and the resulting signal is outputted to the filter circuit FL1.

In the second mode, the power amplifiers 131 and 132 operate in a state in which the load impedance is 1.5 times as compared with the case of the maximum power, and the efficiency decreases with a decrease in the output power.

### (1-3) Third Mode

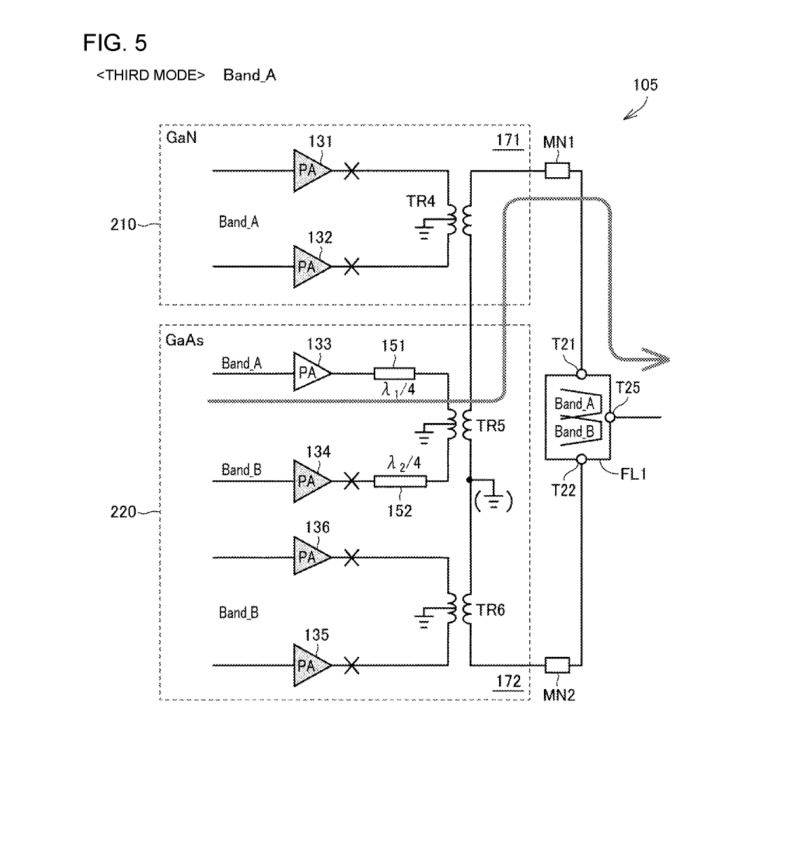

FIG. 5 is a diagram for describing output states of individual amplifiers in a third mode in the case of transmitting an RF signal of FR3.

The third mode is an operation mode that is used when the power level is lower (third power value) than the power level in the second mode. In the third mode, the power amplifiers 131 and 132 formed on or in the substrate 210 are set to a non-driven state in addition to the power amplifiers 134 to 136, and only the power amplifier 133 formed on or in the substrate 220 is set to a driven state.

No phase shift lines are provided at the output ends of the power amplifiers 131 and 132. Thus, when the power amplifiers 131 and 132 are set to a non-driven state, the power amplifiers 131 and 132 have an open-circuit load impedance at the output ends thereof. Thus, the signal amplified by the power amplifier 133 is outputted to the filter circuit FL1 via the transformer TR5 and the transformer TR4.

In the digital ET, the power supply voltage Vcc supplied to a power amplifier is set to be lower in accordance with a decrease in required power. The power amplifiers 131 and 132 using GaN have a large bandgap and are incapable of low voltage operation as compared with the power amplifier 133 using GaAs, and thus the power consumption in a low voltage region is relatively large. Thus, when the power supply voltage Vcc is set so that the power consumption of the power amplifiers 131 and 132 is larger than the power consumption of the power amplifier 133, an increase in the power consumption of the entire power amplifier circuit can be suppressed by performing an amplification operation with use of only the power amplifier 133 using GaAs.

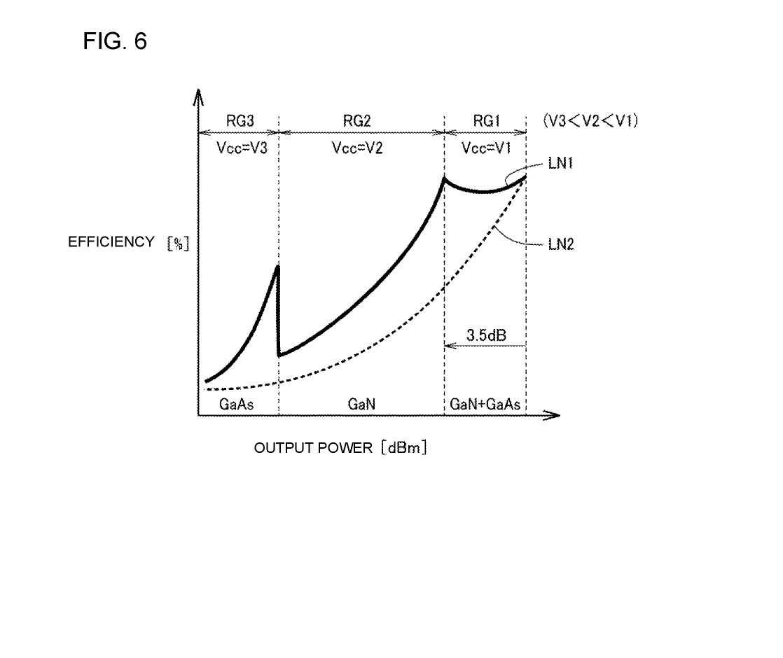

FIG. 6 is a graph for describing the relationship between output power and efficiency in the case of transmitting an RF signal of FR3. In FIG. 6, the horizontal axis indicates the power level of an output signal from the power amplifier circuit 100, and the vertical axis indicates the efficiency of the power amplifier circuit 100. A solid line LN1 indicates the efficiency of the power amplifier circuit 100, whereas a broken line LN2 indicates the efficiency of a class AB amplifier capable of outputting the same maximum power as that of the power amplifier circuit 100.

In the power amplifier circuit 100, the power supply voltage Vcc from the power supply circuit 40 is switched among three levels in accordance with the power level of the input signal TxA. In a region RG1, which is a high output region, the power supply voltage Vcc is set to V1. In a region RG2, which is a medium output region, the power supply voltage Vcc is set to V2 lower than V1 (V1 > V2). In a region RG3, which is a low output region, the power supply voltage Vcc is set to V3 lower than V2 (V2 > V3).

In the region RG1, the first mode is applied, where the power amplifiers 131 and 132 using GaN and the power amplifier 133 using GaAs are driven. In the region RG2, the second mode is applied, where the power amplifiers 131 and 132 using GaN are driven. In the region RG3, the third mode is applied, where only the power amplifier 133 using GaAs is driven.

In the region RG1 and the region RG2, the power amplifiers 131 and 132 are driven in common. Thus, the efficiency smoothly changes at the transition from the first mode to the second mode as indicated by the solid line LN1, and a back-off amount of about 3.5 dB is obtained as described above.

On the other hand, at the transition from the second mode in the region RG2 to the third mode in the region RG3, switching from the power amplifiers 131 and 132 to the power amplifier 133 occurs. Thus, the efficiency can be increased as compared with the case of using the power amplifiers 131 and 132 using GaN, although the change in the efficiency is not smooth.

### (2) UHB

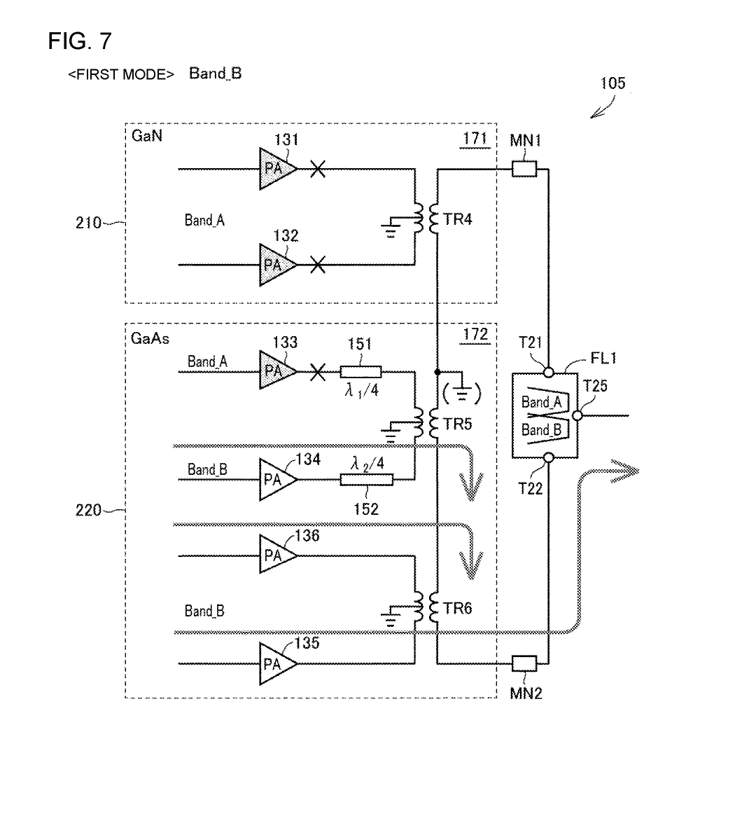

Next, the operations of individual amplifiers in the case of transmitting an RF signal of the UHB frequency band (Band_B) will be described with reference to FIG. 7 to FIG. 9. In the case of transmitting an RF signal of UHB, a power amplifier formed on or in the substrate 220 using GaAs is used in any operation mode.

### (2-1) First Mode

FIG. 7 is a diagram for describing output states of individual amplifiers in a first mode in the case of transmitting an RF signal of UHB. In this operation mode, the power amplifiers 134 to 136 are set to a driven state, and the power amplifiers 131 to 133 are set to a non-driven state.

As a result of the power amplifier 133 being set to a non-driven state, the power amplifier 133 has an open-circuit impedance at the output end thereof, and thus a connection node between the phase shift line 151 and the transformer TR5 and a connection node of the secondary winding of the transformer TR5 with respect to the transformer TR4 have a short-circuit impedance. Accordingly, the signal amplified by the power amplifier 134 is transferred toward the transformer TR6. At this time, the phase of the signal is delayed by 90 degrees by the phase shift line 152.

In the power amplifiers 135 and 136, differential signals transferred from the transformer TR3 are respectively amplified, and the two amplified signals are combined at the transformer TR6.

The phase of an RF signal transferred from the switch circuit 110 to the drive amplifier 122 for the power amplifier 134 is advanced by 90 degrees relative to the phase of an RF signal transferred to the drive amplifier 123 for the power amplifiers 135 and 136. Thus, the phase delay produced by the phase shift line 152 causes a signal generated at the secondary winding of the transformer TR5 to have the same phase as that of a signal generated at the secondary winding of the transformer TR6. Accordingly, the signals amplified by the power amplifiers 135 and 136 and the signal amplified by the power amplifier 134 are combined in the same phase, and the resulting signal is outputted to the filter circuit FL1.

In the first mode, the power amplifiers 134 to 136 and the phase shift line 152 constitute a Doherty amplifier in which the power amplifiers 135 and 136 serve as a carrier amplifier and the power amplifier 134 serves as a peak amplifier. Thus, as the output power decreases, the power amplifier 134 gradually turns off and the load impedance of the power amplifiers 135 and 136 gradually increases, and accordingly the efficiency of the entire amplifier circuit can be increased. When the power amplifier 134 is completely brought into a non-driven state, a back-off amount of about 3.5 dB can be obtained as in the case of FR3.

### (2-2) Second Mode

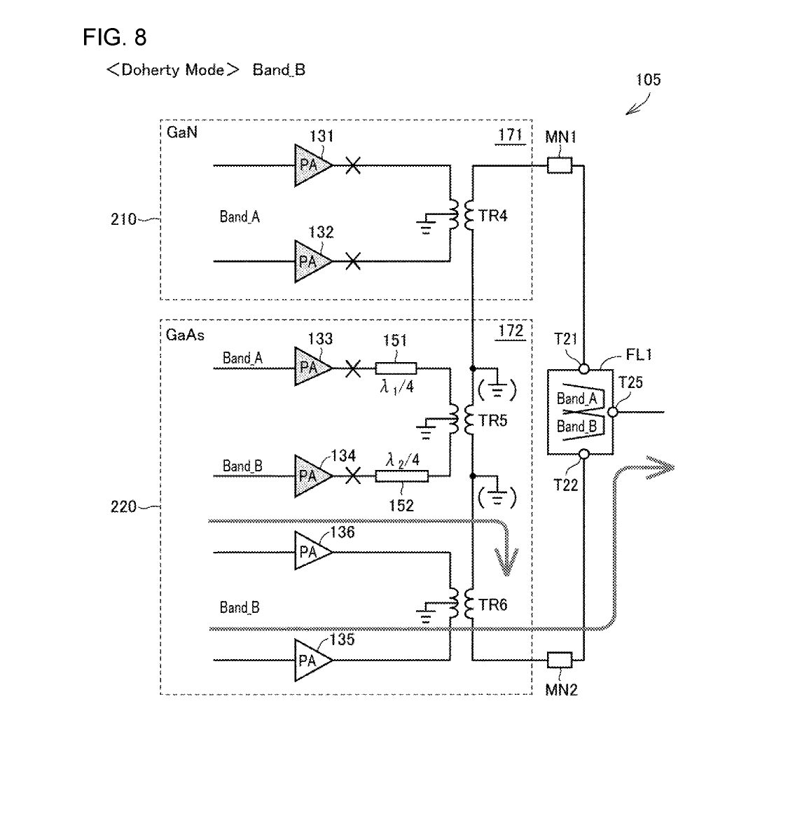

FIG. 8 is a diagram for describing output states of individual amplifiers in a second mode in the case of transmitting an RF signal of UHB.

Also in the case of transmitting an RF signal of UHB, the second mode is an operation mode that is used when the power level is lower (fifth power value) than the power level in the first mode (fourth power value). The value of the power level to switch the operation mode may be the same value as in the case of FR3 or may be a different value.

In the second mode, the power amplifier 134 that functions as a peak amplifier is set to a non-driven state in addition to the power amplifiers 131 to 133 for FR3. In other words, in the second mode, only the power amplifiers 135 and 136 that function as a carrier amplifier are set to a driven state.

At this time, as a result of the power amplifier 134 being set to a non-driven state, a connection node in the secondary winding of the transformer TR5 with respect to the transformer TR6 has a short-circuit impedance. Thus, the signals amplified by the power amplifiers 135 and 136 are combined at the transformer TR6, and the resulting signal is outputted to the filter circuit FL1.

In the second mode, the power amplifiers 135 and 136 operate in a state in which the load impedance is 1.5 times as compared with the case of the maximum power.

### (2-3) Third Mode

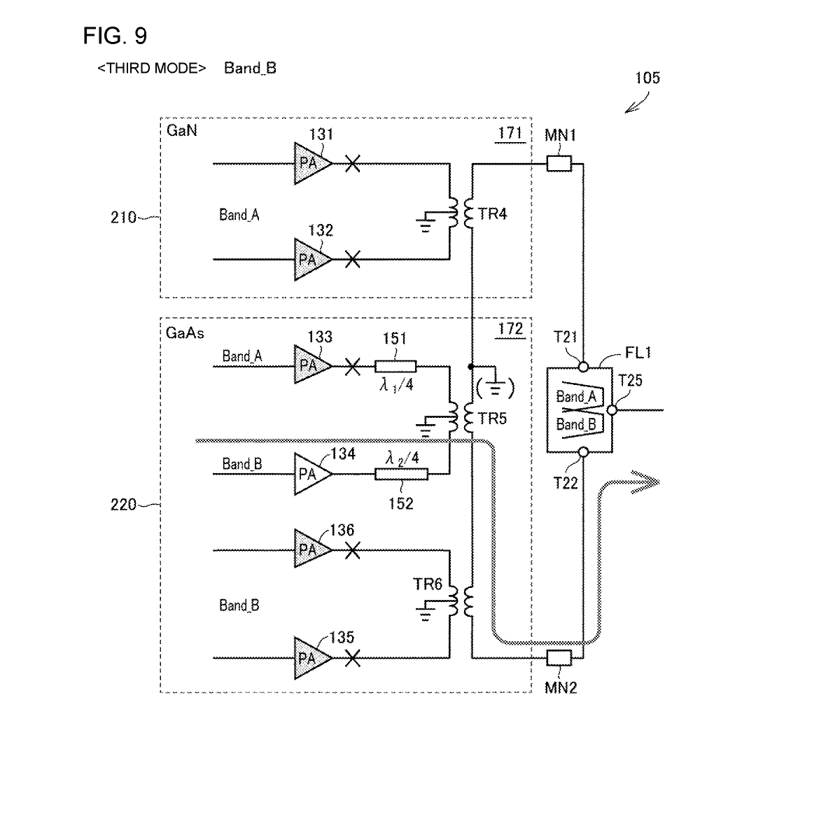

FIG. 9 is a diagram for describing output states of individual amplifiers in a third mode in the case of transmitting an RF signal of UHB.

The third mode is an operation mode that is used when the power level is lower (sixth power value) than the power level in the second mode. In the third mode, the power amplifiers 135 and 136 are set to a non-driven state in addition to the power amplifiers 131 to 133, and only the power amplifier 134 is set to a driven state.

No phase shift lines are provided at the output ends of the power amplifiers 135 and 136. Thus, when the power amplifiers 135 and 136 are set to a non-driven state, the power amplifiers 135 and 136 have an open-circuit load impedance at the output ends thereof, and thus the signal amplified by the power amplifier 134 is outputted to the filter circuit FL1 via the transformer TR5 and the transformer TR6.

All the power amplifiers 134 to 136 used in the case of transmitting an RF signal of UHB are formed on or in the substrate 220 using GaAs. Thus, an issue of an increase in power consumption in a low voltage region does not arise unlike in the case of FR3 using power amplifiers using GaN. Thus, in the case of UHB, it is not always necessary to provide the third mode, but the efficiency can be increased by reducing the number of power amplifiers to be used.

As described above, in the power amplifier circuit, the power amplifiers 131 and 132 formed on or in a wide bandgap semiconductor substrate using GaN (substrate 210) and the power amplifier 133 formed on or in a narrow bandgap semiconductor substrate using GaAs (substrate 220) are used. The use of the power amplifiers 131 and 132 using GaN can implement high output, and the use of the power amplifier 133 using GaAs during low voltage operation can implement low power consumption.

"Substrate 210" and "substrate 220" in the first embodiment correspond to "first substrate" and "second substrate" in the present disclosure, respectively. "Amplification circuit 171", "amplification circuit 172", and "amplification circuit 173" in the first embodiment correspond to "first amplification circuit", "second amplification circuit", and "third amplification circuit" in the present disclosure, respectively. "Power amplifier 131" to "power amplifier 136" in the first embodiment correspond to "first amplifier" to "sixth amplifier" in the present disclosure, respectively. "Filter circuit FL1" and "filter circuit FL2" in the first embodiment correspond to "first filter circuit" and "second filter circuit" in the present disclosure, respectively. "Transformer TR4", "transformer TR5", and "transformer TR6" in the first embodiment correspond to "first transformer", "second transformer", and "third transformer" in the present disclosure, respectively. "Phase shift line 151" and "phase shift line 152" in the first embodiment correspond to "first phase shift line" and "second phase shift line" in the present disclosure, respectively. "Low-noise amplifier 141" and "low-noise amplifier 142" in the first embodiment correspond to "first reception amplifier" and "second reception amplifier" in the present disclosure, respectively.

### Second Embodiment

In the first embodiment, a description has been given of a case where the carrier amplifier in each frequency band of the transmission circuit is constituted by two power amplifiers. In a second embodiment, a description will be given of a case where the carrier amplifier in each frequency band is constituted by one power amplifier.

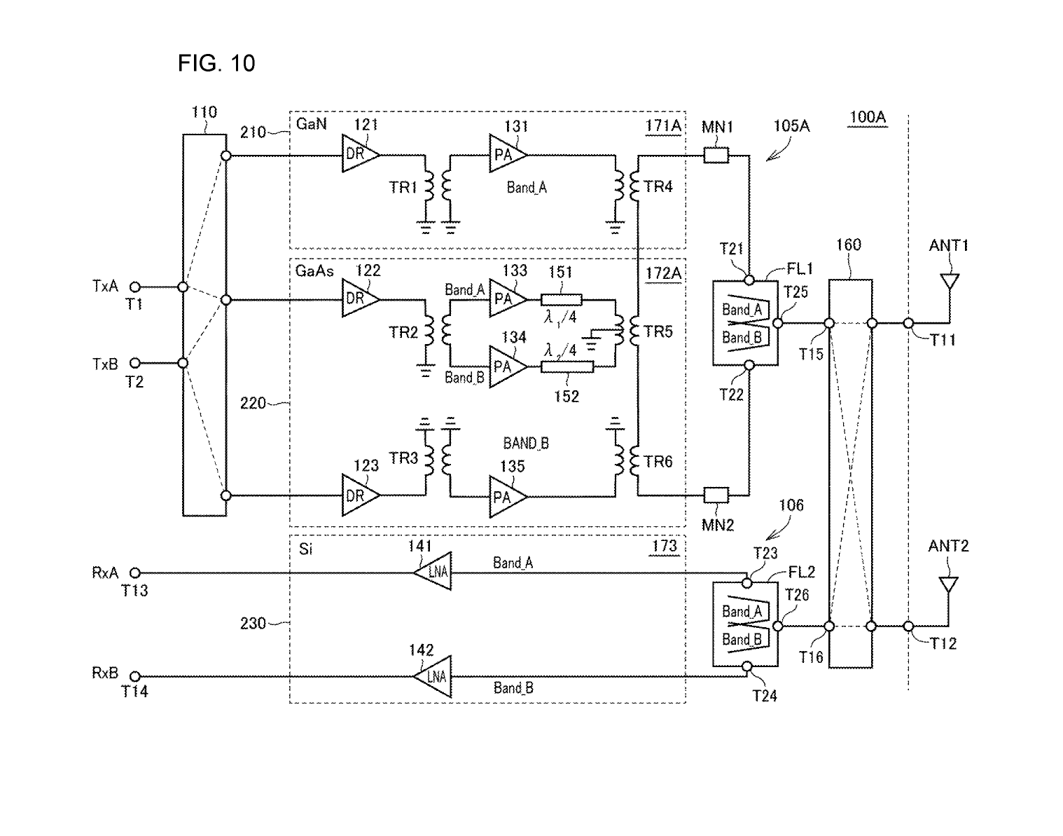

FIG. 10 is a diagram illustrating a detailed configuration of a power amplifier circuit 100A according to the second embodiment. The power amplifier circuit 100A includes amplification circuits 171A and 172A instead of the amplification circuits 171 and 172 of the power amplifier circuit 100 according to the first embodiment.

The amplification circuit 171A does not include the power amplifier 132 of the amplification circuit 171 according to the first embodiment. The amplification circuit 172A does not include the power amplifier 136 of the amplification circuit 172 according to the first embodiment. Regarding the power amplifier circuit 100A, a description of the same elements as those of the power amplifier circuit 100 will not be repeated.

Referring to FIG. 10, in the amplification circuit 171A, one end of the secondary winding of the transformer TR1 is connected to the input end of the power amplifier 131, and the other end thereof is grounded. One end of the primary winding of the transformer TR4 is connected to the output end of the power amplifier 131, and the other end thereof is grounded.

Likewise, in the amplification circuit 172A, one end of the secondary winding of the transformer TR3 is connected to the input end of the power amplifier 135, and the other end thereof is grounded. One end of the primary winding of the transformer TR6 is connected to the output end of the power amplifier 135, and the other end thereof is grounded.

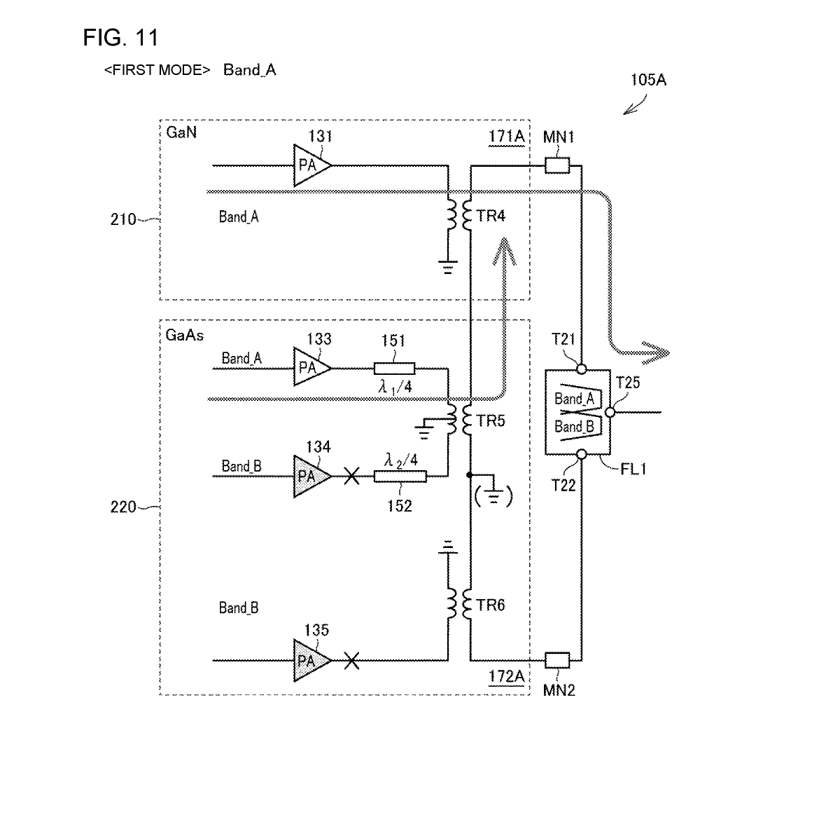

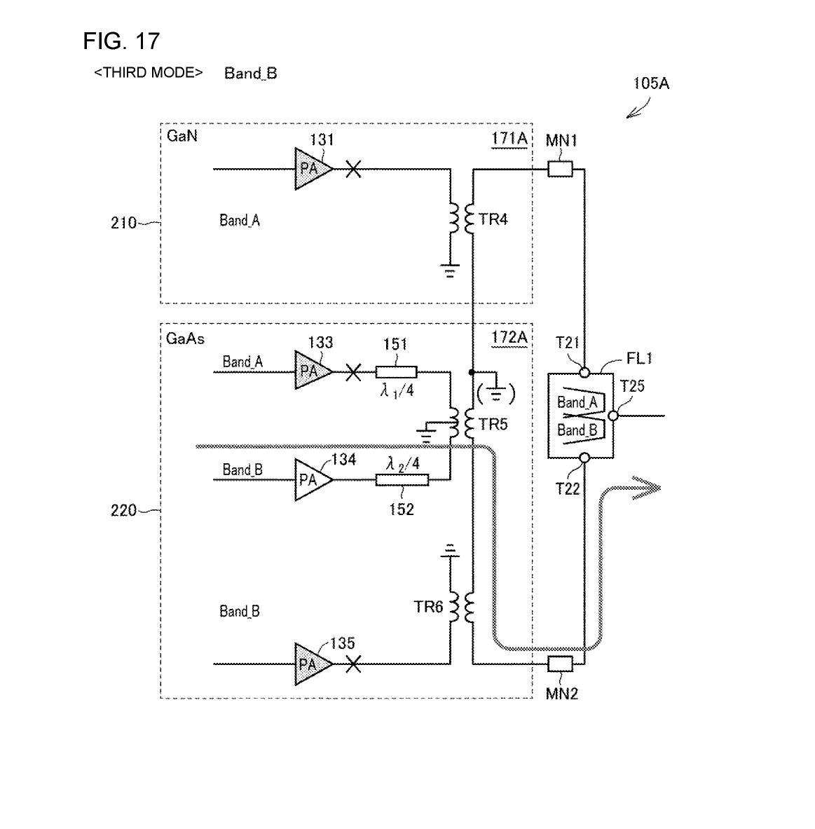

Hereinafter, operation modes in the case of transmitting RF signals of individual frequency bands of FR3 and UHB in the power amplifier circuit 100A will be described with reference to FIG. 11 to FIG. 17.

### 1 FR3

### (1-1) First Mode

FIG. 11 is a diagram for describing output states of individual amplifiers in a first mode in the case of transmitting an RF signal of FR3. In this operation mode, the power amplifiers 131 and 133 are set to a driven state, and the power amplifiers 134 and 136 are set to a non-driven state. In this state, the power amplifiers 131 and 133 and the phase shift line 151 constitute a Doherty amplifier in which the power amplifier 131 serves as a carrier amplifier and the power amplifier 133 serves as a peak amplifier.

As in the first embodiment, as a result of the power amplifier 134 being set to a non-driven state, a connection node of the secondary winding of the transformer TR5 with respect to the transformer TR6 has a short-circuit impedance. Accordingly, the signal amplified by the power amplifier 133 is transferred toward the transformer TR4. At this time, the phase of the signal is delayed by 90 degrees by the phase shift line 151.

The phase of an RF signal transferred from the switch circuit 110 to the drive amplifier 122 for the power amplifier 133 is advanced by 90 degrees relative to the phase of an RF signal transferred to the drive amplifier 121 for the power amplifier 131. Thus, the phase delay produced by the phase shift line 151 causes a signal generated at the secondary winding of the transformer TR5 to have the same phase as that of a signal generated at the secondary winding of the transformer TR4. Accordingly, the signal amplified by the power amplifier 131 and the signal amplified by the power amplifier 133 are combined in the same phase, and the resulting signal is outputted to the filter circuit FL1.

In the first mode, as the output power decreases from the maximum power, the power amplifier 133 functioning as a peak amplifier gradually turns off, and accordingly the load impedance of the power amplifier 131 functioning as a carrier amplifier gradually increases. The increase in the load impedance improves the efficiency of the power amplifier 131.

When the power amplifier 133 is brought into a non-driven state, the load impedance seen from the output end of the power amplifier 131 becomes twice higher, and the number of power amplifiers in use is reduced to one-half. Thus, a back-off amount of about 6 dB can be obtained as a whole.

### (1-2) Second Mode

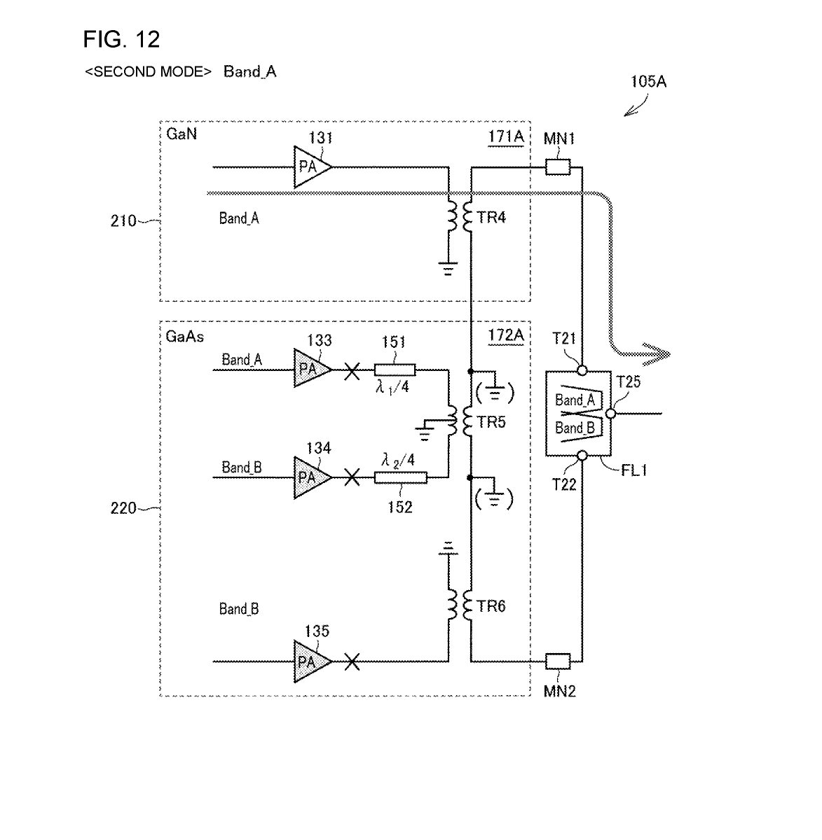

FIG. 12 is a diagram for describing output states of individual amplifiers in a second mode in the case of transmitting an RF signal of FR3.

Also in the second embodiment, the second mode is used when the power level is lower than in the first mode. In the second mode, the power amplifier 133 is set to a non-driven state in addition to the power amplifiers 134 and 135 for UHB. In other words, in the second mode, only the power amplifier 131 formed on or in the substrate 210 is set to a driven state, and the signal amplified by the power amplifier 131 is outputted to the filter circuit FL1.

In the second mode, the power amplifier 131 operates in a state in which the load impedance is twice as compared with the case of the maximum power, and the efficiency decreases with a decrease in output power.

### (1-3) Third Mode

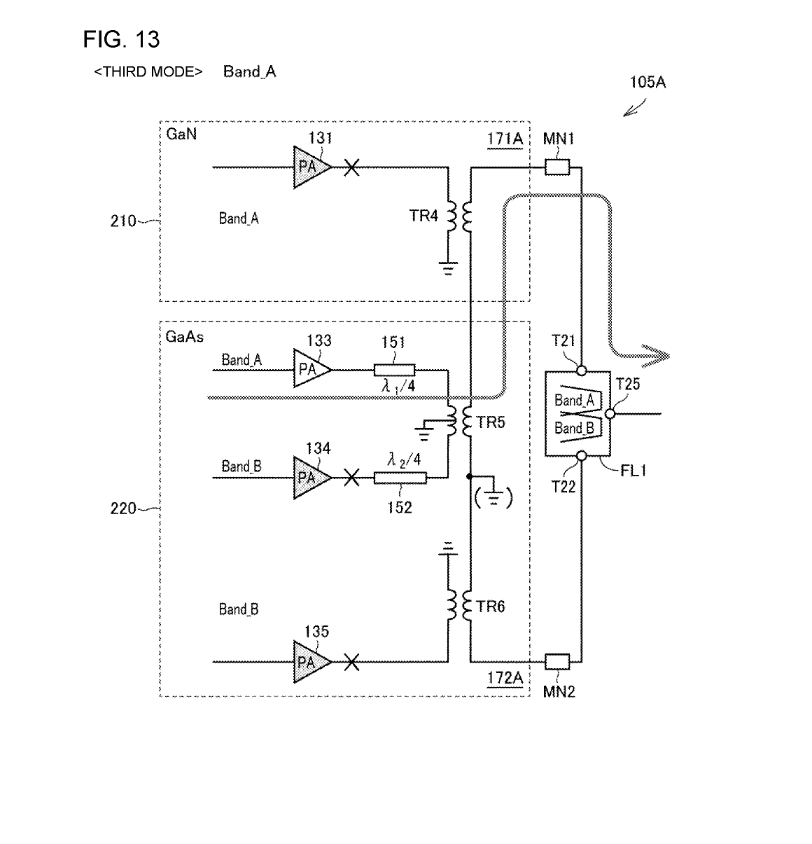

FIG. 13 is a diagram for describing output states of individual amplifiers in a third mode in the case of transmitting an RF signal of FR3.

The third mode is an operation mode that is used when the power level is lower than in the second mode. In the third mode, the power amplifier 131 formed on or in the substrate 210 is set to a non-driven state in addition to the power amplifiers 134 and 135, and only the power amplifier 133 formed on or in the substrate 220 is set to a driven state. Accordingly, the signal amplified by the power amplifier 133 is outputted to the filter circuit FL1.

In the third mode, the power amplifier 131 using GaN is not used, and only the signal amplified by the power amplifier 133 using GaAs is outputted. Accordingly, an increase in the power consumption of the power amplifier circuit 100A in a low voltage region can be suppressed.

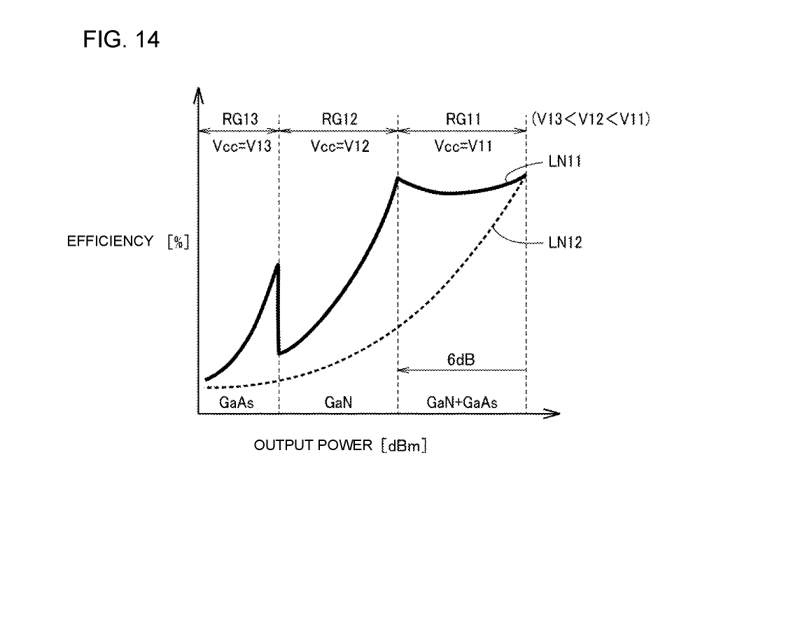

FIG. 14 is a graph for describing the relationship between output power and efficiency in the case of transmitting an RF signal of FR3 in the power amplifier circuit 100A according to the second embodiment. In FIG. 14, the horizontal axis indicates the power level of an output signal from the power amplifier circuit 100A, and the vertical axis indicates the efficiency of the power amplifier circuit 100A. A solid line LN11 indicates the efficiency of the power amplifier circuit 100A, whereas a broken line LN12 indicates the efficiency of a class AB amplifier capable of outputting the same maximum power as that of the power amplifier circuit 100A.

In the power amplifier circuit 100A, the power supply voltage Vcc from the power supply circuit 40 is switched among three levels of V11, V12, and V13 in accordance with the power level of the input signal TxA. In a region RG11, which is a high output region, the power supply voltage Vcc is set to V11. In a region RG12, which is a medium output region, the power supply voltage Vcc is set to V12 lower than V11 (V11 > V12). In a region RG13, which is a low output region, the power supply voltage Vcc is set to V13 lower than V12 (V12 > V13).

In the region RG11, the first mode is applied, where the power amplifier 131 using GaN and the power amplifier 133 using GaAs are driven. In the region RG12, the second mode is applied, where the power amplifier 131 using GaN is driven. In the region RG3, the third mode is applied, where only the power amplifier 133 using GaAs is driven.

Also in the power amplifier circuit 100A, because the power amplifier 131 is driven both in the first mode in the region RG11 and in the second mode in the region RG12, the efficiency smoothly changes at the transition from the first mode to the second mode as indicated by the solid line LN11, and a back-off amount of about 6 dB is obtained.

On the other hand, at the transition from the second mode in the region RG12 to the third mode in the region RG13, switching from the power amplifier 131 to the power amplifier 133 occurs. Thus, the efficiency can be increased as compared with the case of using the power amplifier 131 using GaN, although the change in the efficiency is not smooth.

### (2) UHB

### (2-1) First Mode

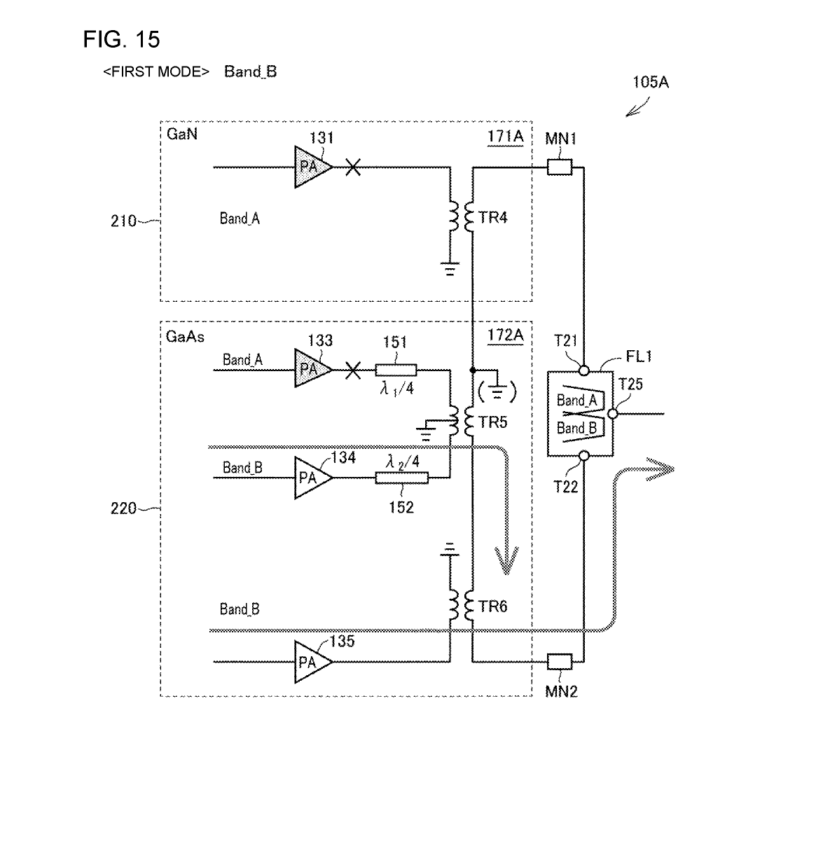

FIG. 15 is a diagram for describing output states of individual amplifiers in a first mode in the case of transmitting an RF signal of UHB. In this operation mode, the power amplifiers 134 and 135 are set to a driven state, and the power amplifiers 131 and 133 are set to a non-driven state. In this state, the power amplifiers 134 and 135 and the phase shift line 152 constitute a Doherty amplifier in which the power amplifier 135 serves as a carrier amplifier and the power amplifier 134 serves as a peak amplifier.

As in the first embodiment, as a result of the power amplifier 133 being set to a non-driven state, a connection node of the secondary winding of the transformer TR5 with respect to the transformer TR4 has a short-circuit impedance. Accordingly, the signal amplified by the power amplifier 134 is transferred toward the transformer TR6. At this time, the phase of the signal is delayed by 90 degrees by the phase shift line 152.

The phase of an RF signal transferred from the switch circuit 110 to the drive amplifier 122 for the power amplifier 134 is advanced by 90 degrees relative to the phase of an RF signal transferred to the drive amplifier 123 for the power amplifier 135. Thus, the phase delay produced by the phase shift line 152 causes a signal generated at the secondary winding of the transformer TR5 to have the same phase as that of a signal generated at the secondary winding of the transformer TR6. Accordingly, the signal amplified by the power amplifier 134 and the signal amplified by the power amplifier 135 are combined in the same phase, and the resulting signal is outputted to the filter circuit FL1.

In the first mode, the power amplifiers 134 and 135 and the phase shift line 152 constitute a Doherty amplifier. Thus, as the output power decreases, the power amplifier 134 gradually turns off and the load impedance of the power amplifier 135 gradually increases, and accordingly the efficiency of the entire amplifier circuit can be increased. When the power amplifier 134 is completely brought into a non-driven state, a back-off amount of about 6 dB can be obtained as in the case of FR3.

### (2-2) Second Mode

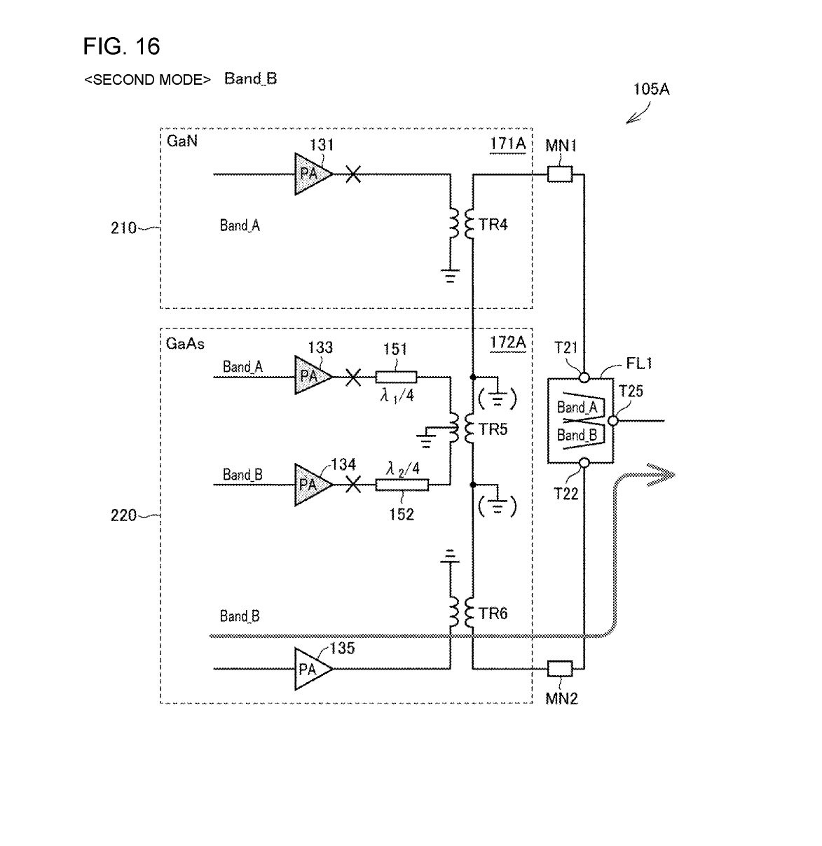

FIG. 16 is a diagram for describing output states of individual amplifiers in a second mode in the case of transmitting an RF signal of UHB.

Also in the case of transmitting an RF signal of UHB, the second mode is an operation mode that is used when the power level is lower than in the first mode.

In the second mode, the power amplifier 134 that functions as a peak amplifier is set to a non-driven state in addition to the power amplifiers 131 and 133 for FR3. In other words, in the second mode, only the power amplifier 135 that functions as a carrier amplifier is set to a driven state. As a result of the power amplifier 134 being set to a non-driven state, the signal amplified by the power amplifier 135 is outputted from the transformer TR6 to the filter circuit FL1.

In the second mode, the power amplifier 135 operates in a state in which the load impedance is twice as compared with the case of the maximum power.

### (2-3) Third Mode

FIG. 16 is a diagram for describing output states of individual amplifiers in a third mode in the case of transmitting an RF signal of UHB.

The third mode is an operation mode that is used when the power level is lower than in the second mode. In the third mode, the power amplifier 135 is set to a non-driven state in addition to the power amplifiers 131 and 133, and only the power amplifier 134 is set to a driven state. Accordingly, the signal amplified by the power amplifier 134 is outputted to the filter circuit FL1.

Also in the power amplifier circuit 100A, in the case of transmitting an RF signal of UHB, the power amplifiers 134 and 135 to be used are both formed on or in the substrate 220 using GaAs, and thus an issue of an increase in power consumption in a low voltage region does not arise. Furthermore, switching from the power amplifier 135 to the power amplifier 134 does not change the number of power amplifiers to be used. Thus, in the power amplifier circuit 100A, it is not always necessary to provide the third mode.

As described above, in the power amplifier circuit 100A, in the case of transmitting an RF signal of FR3 on the higher frequency side, the power amplifier 131 formed on or in a wide bandgap semiconductor substrate using GaN (substrate 210) and the power amplifier 133 formed on or in a narrow bandgap semiconductor substrate using GaAs (substrate 220) are used. The use of the power amplifier 131 using GaN can implement high output, and the use of the power amplifier 133 using GaAs during low voltage operation can implement low power consumption.

In the power amplifier circuit 100A, a larger back-off amount than in the power amplifier circuit 100 according to the first embodiment can be obtained, and thus the efficiency can be further increased. On the other hand, in the power amplifier circuit 100, three power amplifiers can be used at the maximum power although the back-off amount is smaller than in the power amplifier circuit 100A. Thus, the power amplifier circuit 100 may be capable of outputting larger power than the power amplifier circuit 100A when the outputs of the individual power amplifiers are equivalent to each other.

### Third Embodiment

In the first and second embodiments, a description has been given of the configurations in which antennas for respective frequency bands are individually provided. In a third embodiment, a description will be given of a configuration in which a common antenna capable of radiating radio waves of both frequency bands is provided.

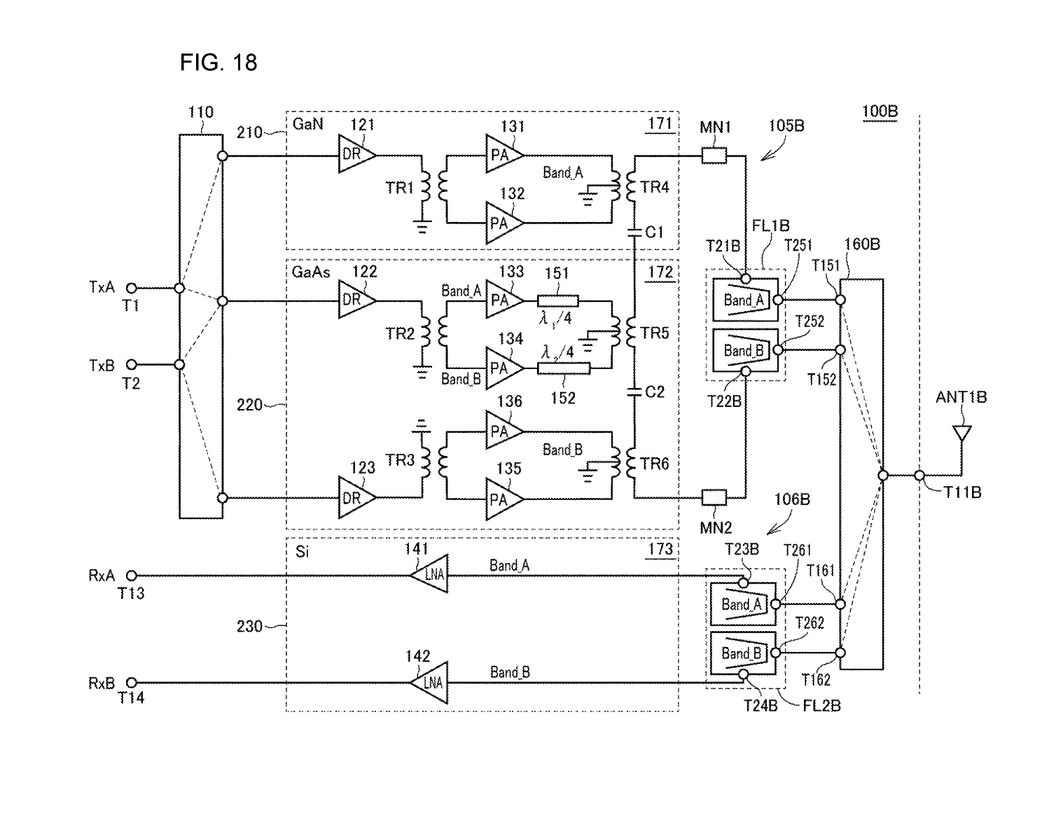

FIG. 18 is a diagram illustrating a detailed configuration of a power amplifier circuit 100B according to the third embodiment. The power amplifier circuit 100B includes a switch circuit 160B instead of the switch circuit 160 of the power amplifier circuit 100 according to the first embodiment, and also includes filter circuits FL1B and FL2B instead of the filter circuits FL1 and FL2. Furthermore, a single antenna ANT1B capable of covering the frequency bands of FR3 and UHB is provided as an antenna for transmitting and receiving radio waves. Regarding the power amplifier circuit 100B, a description of the same elements as those of the power amplifier circuit 100 will not be repeated.

Referring to FIG. 18, the filter circuit FL1B included in a transmission circuit 105B and the filter circuit FL2B included in a reception circuit 106B each have a configuration in which a band pass filter for FR3 and a band pass filter for UHB are individually provided instead of the diplexer according to the first embodiment.

More specifically, in the filter circuit FL1B, a terminal T21B of the filter for FR3 is connected to one end of the secondary winding of the transformer TR4, and a terminal T251 is connected to a transmission terminal T151 of the switch circuit 160B. A terminal T22B of the filter for UHB is connected to the other end of the secondary winding of the transformer TR6, and a terminal T252 is connected to a transmission terminal T152 of the switch circuit 160B. The filter circuit FL1B removes unwanted waves in output signals from the individual amplification circuits and transfers an RF signal to the switch circuit 160B.

In the filter circuit FL2B of the reception circuit 106B, a terminal T23B of the filter for FR3 is connected to the input end of the low-noise amplifier 141, and a terminal T261 is connected to a reception terminal T161 of the switch circuit 160B. A terminal T24B of the filter for UHB is connected to the input end of the low-noise amplifier 142, and a terminal T262 is connected to a reception terminal T162 of the switch circuit 160B. The filter circuit FL2B separates, from an RF signal received by the antenna ANT1B, a signal of the frequency band corresponding to FR3 or UHB, and outputs the resulting signal to the corresponding low-noise amplifier.

The switch circuit 160B switches the connection of the antenna ANT1B connected to an antenna terminal T11B with respect to the transmission terminals T151 and T152 and the reception terminals T161 and T162.

In the power amplifier circuit 100B, the filters for the respective frequency bands are individually provided in the filter circuits FL1B and FL2B. Thus, signals of different frequency bands can be simultaneously transmitted and received. Specifically, transmission of an FR3 signal and reception of a UHB signal can be simultaneously performed. Alternatively, transmission of a UHB signal and reception of an FR3 signal can be simultaneously performed.

For example, when transmission of an FR3 signal and reception of a UHB signal are simultaneously performed in a configuration that uses a diplexer as a filter circuit, such as the power amplifier circuit 100 according to the first embodiment, the FR3-side circuit in the filter circuit FL2 is seen from the transmission circuit 105 due to the common terminal T26 in the filter circuit FL2, and the transmission signal is degraded by 3 dB. Thus, in the case of using a single antenna in a configuration that uses a diplexer as a filter circuit, it is necessary to separate the timing to transmit radio waves and the timing to receive radio waves.

As described above, in the configuration of transmitting and receiving RF signals of FR3 and UHB by a single common antenna, a power amplifier using a GaN having a high output capacity is used when high output power is necessary, and a power amplifier using GaAs is used in a low voltage region. Accordingly, it is possible to implement high output while reducing power consumption at low voltages.

The embodiments disclosed herein are to be considered illustrative and not restrictive in all respects. The scope of the present disclosure is defined not by the foregoing description of the embodiments but by the claims, and is intended to encompass all changes within the meaning and scope equivalent to the claims.

What is claimed is:

1. A power amplifier circuit for amplifying a radio frequency signal supplied from a signal processing circuit and transmitting the radio frequency signal to an antenna, the power amplifier circuit comprising:
an input terminal at which the radio frequency signal to be transmitted is received from the signal processing circuit;
a transmission terminal via which the radio frequency signal is transmitted to the antenna; and
a transmission circuit configured to amplify the radio frequency signal received at the input terminal and to transmit the radio frequency signal to the antenna via the transmission terminal, wherein
the transmission circuit includes
a first substrate and a second substrate each comprising a semiconductor substrate including a material mainly composed of a compound of Group III and Group V elements,
a first amplification circuit formed on or in the first substrate, and
a second amplification circuit formed on or in the second substrate,
the first substrate is a wide bandgap semiconductor substrate, and
the second substrate is a narrow bandgap semiconductor substrate.

2. The power amplifier circuit according to claim 1, wherein
the first amplification circuit includes
a first amplifier and a second amplifier, and
a first transformer configured to combine an output signal from the first amplifier and an output signal from the second amplifier,
the second amplification circuit includes
a third amplifier,
a first phase shift line connected to an output end of the third amplifier, and
a second transformer,
a first end of a primary winding of the second transformer is connected to the third amplifier via the first phase shift line,
a first end of a secondary winding of the first transformer is connected to the transmission terminal, and
a second end of the secondary winding of the first transformer is connected to one end of a secondary winding of the second transformer.

3. The power amplifier circuit according to claim 2, wherein
the transmission circuit is configured so that an operation mode thereof is switched in accordance with a power level of the radio frequency signal to be output, and
when the power level of the radio frequency signal to be output has a first power value, the first amplifier, the second amplifier, and the third amplifier are set to a driven state.

4. The power amplifier circuit according to claim 3, wherein
when the power level of the radio frequency signal to be output has a second power value smaller than the first power value,
the first amplifier and the second amplifier are set to a driven state, and
the third amplifier is set to a non-driven state.

5. The power amplifier circuit according to claim 4, wherein
when the power level of the radio frequency signal to be output has a third power value smaller than the second power value,
the first amplifier and the second amplifier are set to a non-driven state, and
the third amplifier is set to a driven state.

6. The power amplifier circuit according to claim 2, wherein
the transmission circuit further includes a first filter circuit connected to the transmission terminal and configured to selectively transfer a signal of a first frequency band and a signal of a second frequency band to the transmission terminal,
the second amplification circuit includes
a fourth amplifier, a fifth amplifier, and a sixth amplifier,
a second phase shift line connected to an output end of the fourth amplifier, and
a third transformer configured to combine an output signal from the fifth amplifier and an output signal from the sixth amplifier,
a second end of the primary winding of the second transformer is connected to the output end of the fourth amplifier via the second phase shift line,
the first end of the secondary winding of the first transformer and a first end of a secondary winding of the third transformer are connected to the first filter circuit, and
a second end of the secondary winding of the third transformer is connected to a second end of the secondary winding of the second transformer.

7. The power amplifier circuit according to claim 6, wherein
the second frequency band is lower than the first frequency band,
the first amplifier, the second amplifier, and the third amplifier are used when transmitting in the first frequency band, and
the fourth amplifier, the fifth amplifier, and the sixth amplifier are used when transmitting in the second frequency band.

8. The power amplifier circuit according to claim 7, wherein
the first frequency band ranges from 7.0 GHz to 10 GHz, and
the second frequency band ranges from 3.3 GHz to 5.0 GHz.

9. The power amplifier circuit according to claim 7, wherein
when transmitting in the first frequency band, the fourth amplifier, the fifth amplifier, and the sixth amplifier are set to a non-driven state, and
when transmitting in the second frequency band, the first amplifier, the second amplifier, and the third amplifier are set to a non-driven state.

10. The power amplifier circuit according to claim 7, wherein
when transmitting in the second frequency band,
when a power level of the radio frequency signal to be output has a fourth power value, the fourth amplifier, the fifth amplifier, and the sixth amplifier are set to a driven state.

11. The power amplifier circuit according to claim 10, wherein
when transmitting in the second frequency band,
when a power level of the radio frequency signal to be output has a fifth power value smaller than the fourth power value,
the fifth amplifier and the sixth amplifier are set to a driven state, and
the fourth amplifier is set to a non-driven state.

12. The power amplifier circuit according to claim 11, wherein
when transmitting a radio frequency signal of the second frequency band,
when a power level of the radio frequency signal to be output has a sixth power value smaller than the fifth power value,
the fifth amplifier and the sixth amplifier are set to a non-driven state, and
the fourth amplifier is set to a driven state.

13. The power amplifier circuit according to claim 6, wherein
the first phase shift line has an electrical length of a quarter wavelength at a center frequency of the first frequency band, and
the second phase shift line has an electrical length of a quarter wavelength at a center frequency of the second frequency band.

14. The power amplifier circuit according to claim 1, wherein
the first amplification circuit includes
a first amplifier, and
a first transformer connected to an output end of the first amplifier,
the second amplification circuit includes
a third amplifier,
a first phase shift line connected to an output end of the third amplifier, and
a second transformer,
a first end of a primary winding of the second transformer is connected to the third amplifier via the first phase shift line,
a first end of a secondary winding of the first transformer is connected to the transmission terminal, and
a second end of the secondary winding of the first transformer is connected to a first end of a secondary winding of the second transformer.

15. The power amplifier circuit according to claim 14, further comprising:
a first filter circuit connected to the transmission terminal and configured to selectively transfer a signal of a first frequency band and a signal of a second frequency band to the transmission terminal, wherein
the second amplification circuit includes
a fourth amplifier and a fifth amplifier,
a second phase shift line connected to an output end of the fourth amplifier, and
a third transformer connected to an output end of the fifth amplifier,
a second end of the primary winding of the second transformer is connected to the output end of the fourth amplifier via the second phase shift line,
the first end of the secondary winding of the first transformer and a first end of a secondary winding of the third transformer are connected to the first filter circuit, and
a second end of the secondary winding of the third transformer is connected to a second end of the secondary winding of the second transformer.

16. The power amplifier circuit according to claim 1, wherein the first amplification circuit and the second amplification circuit constitute a Doherty amplifier.

17. The power amplifier circuit according to claim 1, wherein
the first substrate is a semiconductor substrate including a material mainly composed of a base material of gallium nitride (GaN), and
the second substrate is a semiconductor substrate including a material mainly composed of a base material of gallium arsenide (GaAs).

18. The power amplifier circuit according to claim 1, wherein
the power amplifier circuit is configured to amplify a radio frequency signal received from the antenna and transfer the radio frequency signal to the signal processing circuit, and
the power amplifier circuit further comprises:
a reception terminal at which a radio frequency signal received by the antenna is received;
an output terminal via which the radio frequency signal is outputted to the signal processing circuit; and
a reception circuit configured to amplify the radio frequency signal received at the reception terminal and output the radio frequency signal to the signal processing circuit via the output terminal.

19. The power amplifier circuit according to claim 18, wherein
the reception circuit includes
a second filter circuit connected to the reception terminal and configured to separate the radio frequency signal received from the antenna into a signal of a first frequency band and a signal of a second frequency band, and
a third amplification circuit including a first reception amplifier and a second reception amplifier,
the first reception amplifier is configured to amplify the signal of the first frequency band separated by the second filter circuit, and
the second reception amplifier is configured to amplify the signal of the second frequency band separated by the second filter circuit.

20. The power amplifier circuit according to claim 19, wherein the third amplification circuit is formed on or in a semiconductor substrate including a material mainly composed of a Si-based material.
